(19) United States
(12) Patent Application Publication
(10) Pub. No.: US 2006/0181437 A1
(43) Pub. Date: Aug. 17, 2006

(54) Bus system

(75) Inventors: Martin Brox, Munchen (DE); Michael Markert, Augsburg (DE); Manfred Plan, Munchen (DE); Peter Schrogmeier, Munchen (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munchen (DE)

(21) Appl. No.: 11/262,960

(22) Filed: Nov. 1, 2005

(30) Foreign Application Priority Data
Nov. 2, 2004 (DE) 10 2004 052 903.5

(51) Int. Cl. H03M 7/00

(52) U.S. Cl. 341/50

(57) ABSTRACT

The invention relates to a procedure for operating a bus system, as well as a bus system with a line, and two adjoining lines, whereby the lines each comprise two line sections, which are connected with one another by means of a line amplifier and/or buffer device, and whereby the line amplifier and/or buffer device connected with the line sections of the line is constructed as an inverting line amplifier and/or buffer device, and the line amplifier and/or buffer devices connected with the line sections of the adjoining lines are constructed as non-inverting line amplifier and/or buffer devices, or vice versa.

### CLAIM FOR PRIORITY

This application claims the benefit of priority to German Application No. 10 2004 052 903.5 which was filed in the German language on Nov. 2, 2004, the contents of which are hereby incorporated by reference.

### TECHNICAL FIELD OF THE INVENTION

The invention relates to a bus system and procedure, and in particular, to a bus system with a line, and two adjoining lines, whereby the lines each have two line sections connected with one another by means of a line amplifier and/or buffer device.

### BACKGROUND OF THE INVENTION

In electrical or electronic systems, individual system modules, for instance various electronic assemblies, various electronic components in each case installed on individual assemblies (for instance various semi-conductor components installed on an individual assembly), various sub-components provided on one and the same component (in particular various components of a semi-conductor component, for instance a memory component), etc. communicate via a transfer medium—for instance a bus system—consisting of one or more transfer lines.

Bus systems, for instance a corresponding chip-internal bus system, can be jointly used by several, in particular by two or more than two modules/components, and can for instance consist of several partial systems, for example of one data bus—consisting of one or more data lines—for the transfer of the actual useful data, and/or one address bus—consisting of one or more address lines—for transferring address—data, and/or one control bus—consisting of one or more control lines—for transferring control data, etc.

The signal delay time τ of a signal relayed via a line of a bus system is determined by the RC constant of the line, whereby the following applies:
τ≈0.7RC.

For the resistance R of a line the following applies:
R=(L/W)Rₛₕ
where L is the length of the line, W its width, and Rₛₕ its respective specific resistance. For a width W of for instance 0.5 μm and a specific resistance of for instance 0.04Ω/sq, the following resistance per length then results:
R_{L}=80Ω/mm.

The above specific resistance of for instance 0.04Ω/sq is a typical value for chip-internal aluminum wiring lines of semi-conductor components, in particular memory components, in particular for aluminum wiring lines of the uppermost wiring and/or metallization level.

In semi-conductor components for chip-internal buses in general only the above uppermost wiring level is used for relatively long buses and/or bus lines (i.e. for instance for lengths up to 5 mm or 10 mm); lines provided on other wiring levels have too high an impedance to achieve for the above line lengths sufficiently low signal delay times τ.

The above capacitance C of a line—provided on the uppermost wiring level of a semi-conductor component—essentially consists of a so-called “horizontal capacitance” CH (i.e. the capacitance relating to corresponding neighboring lines on the same—uppermost—metallization level), and of a so-called “vertical capacitance” CV (i.e. the capacitance relating to corresponding lines in deeper metallization levels).

Typical values for horizontal and vertical capacitances per length are for instance CH_{L}=100 fF/mm, and CV_{L}=100 fF/mm.

As indicated above, a bus system comprises a plurality of lines—in particular lines lying next to one another on a corresponding level, for instance on the uppermost metallization level.

The actual effective capacitance C of a line can therefore also be relatively strongly dependent on a signal present on a particular line (which in simple terms (in particular in digital systems) can, at a particular instant, remain the same, increase or decrease), and on signals present on the respective immediately adjacent neighboring lines on the same metallization level (whereby the signal present on a first neighboring line (lying for instance to the left of the line) can, at a particular instant, remain the same, increase or decrease, and whereby the signal present on a second neighboring line (lying for instance to the right of the line) can, at a particular instant, also remain the same, increase or decrease).

When the signal present on the respective line and the signal present on an immediately adjacent neighboring line both remain constant, and/or both increase or decrease, this has no effect on the actual effective capacitance C of a line (Case 1: both signals are moving in the same direction).

When, in contrast, the signal present on the respective line remains constant (or alternatively for instance increases or decreases), and the signal present on an immediately adjacent line increases or decreases (or alternatively for instance remains constant), this results in a single additional capacitance to the extent of for instance 1 CV, due to the difference in signal movements (Case 2: the signals are moving in a single opposed direction).

If the signal present on the respective line increases (or alternatively decreases), and the signal present on an immediately neighboring line decreases (or alternatively increases), this results in double the additional capacitance to the extent of for instance 2 CV, due to the counter-motion in signal movements (Case 3: the signals are moving in an opposing direction).

In order to represent the various cases occurring in a line and two neighboring lines lying to the left and to the right of that line, the following symbols can for instance be used:

| Symbol | Signal state |
|---|---|
| + | signal increasing (“positive flank”) |
| O | signal remains constant |
| − | signal decreasing (“negative flank”) |

For the actual effective capacitance per length CL the following different values in total can therefore arise on a particular line—depending on the signals present on that line and on the respective neighboring lines—(here represented by means of the example of an increasing signal present on the line in question):

| Signal state | | Signal state | |
|---|---|---|---|
| in the neigh- | | in the neigh- | |
| boring line | Signal state | boring line | |
| lying to the | in the | lying to the | Effective |
| left of the | respective | right of the | capacitance per |
| respective line | line | respective line | length C_{L} |
| + | + | + | CH_{L} |
| + | + | O | CH_{L} + 1CV_{L} |
| + | + | − | CH_{L} + 2CV_{L} |
| o | + | O | CH_{L} + 2CV_{L} |
| − | + | O | CH_{L} + 3CV_{L} |
| − | + | − | CH_{L} + 4CV_{L} |

The resulting actual effective capacitance per length C_{L} of a line can therefore—depending on the data patterns present on that line and on the neighboring lines—fluctuate rather strongly (in the present example for instance between the minimum and/or maximum values C_{L,min}=100 fF/mm and C_{L,max}=500 fF/mm).

In terms of the above formula and with a bus length and/or bus line length of for instance 6 mm, the resulting maximum signal delay time τₘₐₓ is:
τₘₐₓ≈0.7RCₘₐₓ>1 ns

This signal delay period is too long for many applications.

For this reason a corresponding bus line can for instance be subdivided into two essentially equally long sections for example, connected by means of an appropriate line amplifier device and/or appropriate line amplifier buffer. The line amplifier device does however cause a signal delay time that is increased by the addition of a buffer signal delay time τbuffer. A typical value for the buffer signal delay time τ_{buffer} is 200 ps.

The signal delay time caused by a line and/or line section however is dependent on the square of the length L of the line and/or of the respective line section, in accordance with the formula:
τ≈0.7 R_{L}C_{L}L²

The resulting signal delay time τ_{ges} for the above line—subdivided into two essentially equally long line sections connected by means of a line amplifier device—therefore amounts to:
τ_{ges}=τ_{buffer}+2τ

For a total line length of 6 mm and two 3 mm long line sections, a minimum total signal delay time τ_{ges,min} of 300 ps, and a maximum total signal delay time τ_{ges,max} of 700 ps therefore results (i.e. a substantially shorter maximum signal delay time than for the 6 mm long line—not divided into two sections connected by means of a line amplifier device—quoted above).

For high-speed applications in particular, the above difference—which depends on the respective data pattern present on the lines and on corresponding neighboring lines—between the minimum total signal delay time τ_{ges,min}, and the maximum total signal delay time τ_{ges,max} is not admissible.

For this reason so-called screening lines can be provided between two corresponding lines of a bus system which relay actual data, address or control signals.

These screening lines constantly remain in the state identified by the above symbol “o” (i.e. the signal remains constant).

An example of a solution of this nature for instance is given in C. Yoo et al, Int. Solid State Circuits Conference, ISSCC-2003 (17-7).

The number of different data patterns possible for a particular line and its neighboring lines are reduced to the following cases when using screening lines:

| Signal state of the | | Signal state of the |
|---|---|---|
| screening line lying | | screening line lying |
| to the left of the | | to the right of the |
| respective | Signal state of the | respective |
| neighboring line | respective line | neighboring line |
| O | + | O |
| O | O | O |
| O | − | O |

The difference between the minimum total signal delay time τ_{ges,min}, and the maximum total signal delay time τ_{ges,max}, which depends on the respective data patterns present on the lines and corresponding neighboring lines can thereby be reduced.

Here a disadvantage does inter alia arise, that due to the above high possible number of lines additionally required (namely the above screening lines), the chip area required for a particular semi-conductor, in particular a memory component, is increased.

### SUMMARY OF THE INVENTION

The invention is aimed at providing a novel bus system, as well as a novel procedure for operating a bus system.

In one embodiment of the invention, there is a bus system, with a line and two adjoining lines, whereby the lines each comprise two line sections, which are connected with one another by means of a line amplifier and/or buffer device, characterized in that the line amplifier and/or buffer device connected with the line sections of the line is constructed as an inverting line amplifier and/or buffer device, and the amplifier and/or buffer devices connected with the line sections of the adjoining lines are constructed as non-inverting line amplifier and/or buffer devices.

In another embodiment of the invention, there is a bus system, with a line and two adjoining lines, whereby the lines each comprise two line sections, which are connected with one another by means of a line amplifier and/or buffer device, characterized in that the line amplifier and/or buffer device connected with the line sections of the line is constructed as a non-inverting line amplifier and/or buffer device, and the line amplifier and/or buffer devices connected with the line sections of the adjoining lines are constructed as inverting line amplifier and/or buffer devices.

In still another embodiment of the invention, there is a procedure for operating a bus system, with a line, and two adjoining lines, whereby the lines each comprise two line sections, which are connected with one another by means of a line amplifier and/or buffer device, the procedure inverting amplification and/or buffering of the signals present on the line by means of the line amplifier and/or buffer device connected with the line sections of the line; and non-inverting amplification and/or buffering of the signals present on the adjoining lines by means of the line amplifier and/or buffer devices connected with the line sections of the adjoining lines.

In addition, in terms of yet another embodiment of the invention, there is a procedure for operating a bus system with a line and two adjoining lines, whereby the lines each comprise two line sections, which are connected with one another by means of a line amplifier and/or buffer device, the procedure comprising non-inverting amplification and/or buffering of the signals present on the line by means of the line amplifier and/or buffer device connected with the line sections of the line; and inverting amplification and/or buffering of the signals present on the adjoining lines by means of the line amplifier and/or buffer devices connected with the line sections of the adjoining lines.

In this way—even without the use of screening lines—the dependence of the signal delay times τ_{ges} caused by the lines on the data patterns present on the lines can be reduced, and/or—in the case where the separate line sections are advantageously of the same length—the signal delay times τ_{ges} caused by the lines can be made independent from the data patterns present on the lines.

### BRIEF DESCRIPTION OF THE DRAWINGS

The invention is described below in more detail with reference to the exemplary embodiments and figures, in which:

FIG. 1 shows, as an example, a semi-conductor component with a plurality of components communicating with one another via a bus system in terms of one embodiment example of the invention.

FIG. 2 shows, as an example, a cross-section of the semi-conductor component section shown in FIG. 1, to illustrate several metallization and/or wiring levels provided in the semi-conductor component.

### DETAILED DESCRIPTION OF THE INVENTION

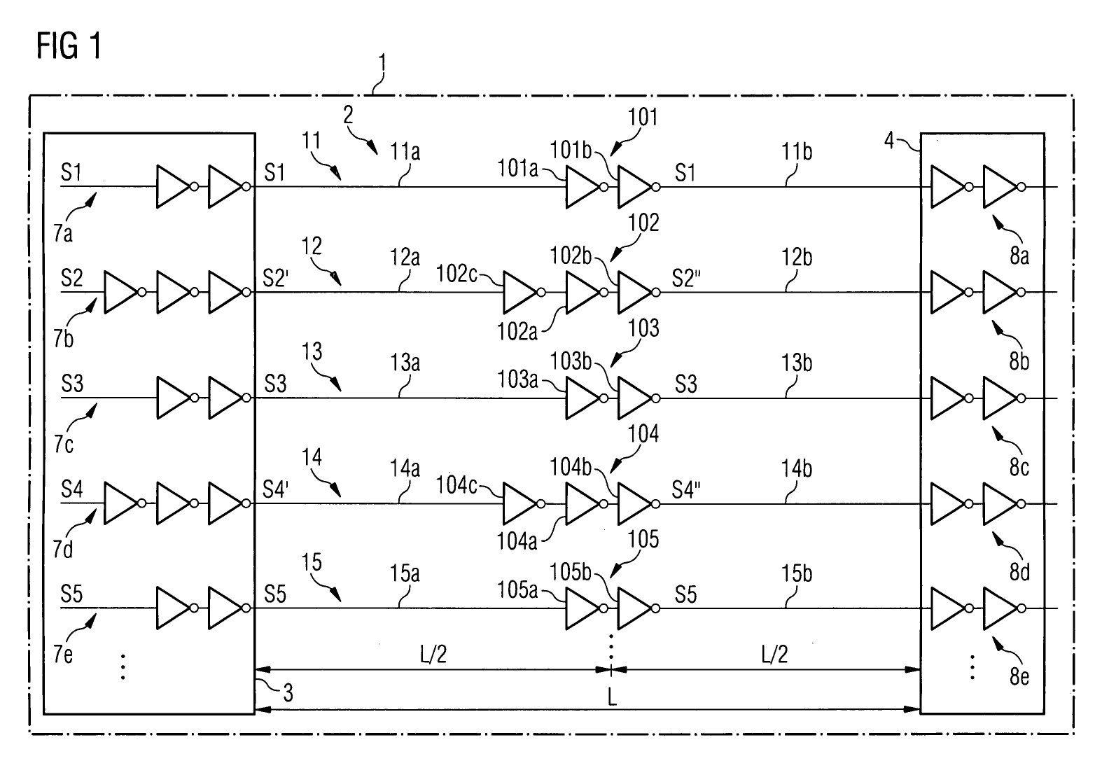

FIG. 1 shows a schematic representation of a section of a semi-conductor component 1.

The semi-conductor component 1 can for instance be a corresponding integrated (analog and/or digital) computing circuit and/or memory component, for instance a microprocessor and/or microcontroller and/or memory component (for instance a function memory component (PLA, PAL, etc.) and/or table memory component (for instance ROM or RAM)).

In particular the semi-conductor component 1 can be a SRAM (Static Random Access Memory) or DRAM (Dynamic Random Access Memory), for instance a DDR and/or DDR2-DRAM.

As is illustrated schematically in FIG. 1, the semi-conductor component 1 includes a plurality of different components 3, 4, whereby two or more different components (for instance the components 3, 4, shown in FIG. 1 and—alternatively—one or more further components, not shown here) communicate with one another via a corresponding bus system 2.

As is apparent from FIG. 1, the bus system 2 includes a plurality of lines 11, 12, 13, 14, 15 (and where appropriate, a plurality of further corresponding lines not shown here).

The bus system shown in FIG. 1 can include a plurality of partial systems, for example a data bus—including one ore more data lines—for the transfer of the actual useful data, and/or of an address bus—including one or more address lines—for the transfer of address data and/or of a control bus—including one or more control lines—for the transfer of control data, etc.

More than 10, 30, 60 or 120 lines can for instance be provided for the above address bus—according to the width of the address bus—, for instance 64 or 128 lines, etc.

Accordingly more than for instance 10, 20, or 30 lines can be provided for the data bus—corresponding with the width of the data bus—, for instance 32 or 64 lines, etc., and for the control bus for instance more than 2, 4 or 8 lines, for instance 8 or 16 lines, etc.

The principal operating method and functioning of the chip-internal bus system 2 shown in FIG. 1 in terms of the embodiment example of the invention, and more closely described below, (and/or the elements employed for it) can accordingly also be used in any bus systems other than just the chip-internal bus system 2 shown here, for instance in (external) bus systems with which the various electronic assemblies of an electronic systems are connected with one another, and/or in bus systems, with which various electronic components, in each case arranged on a single assembly and/or printed circuit board (for instance various semi-conductor components arranged on a single assembly and/or printed circuit board) are connected with one another, etc., etc.

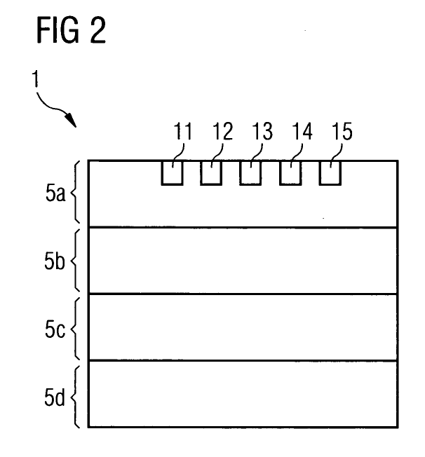

As is apparent from FIG. 2, the above lines 11, 12, 13, 14, 15 of the bus system 2 can advantageously be arranged on an uppermost wiring and/or metallization level 5a of several superimposed wiring and/or metallization levels 5a, 5b, 5c, 5d of the semi-conductor component 1, whereby corresponding additional lines (for example corresponding additional lines of one or more additional bus systems, not shown here) can also be provided in one or more wiring and/or metallization levels 5b, 5c, 5d, lying underneath the uppermost wiring and/or metallization levels 5a.

The above uppermost wiring and/or metallization level 5a can for instance be a corresponding aluminum wiring level, and accordingly the above lines 11, 12, 13, 14, of the bus systems 2, can advantageously be aluminum wiring lines.

The lines 11, 12, 13, 14, 15 can exhibit a specific resistance Rₛₕ of for instance between 0.005Ω/sq and 0.1Ω/sq, in particular between 0.01Ω/sq and 0.07Ω/sq, for example ca. 0.04Ω/sq.

The width W of the above lines 11, 12, 13, 14, 15 can for instance amount to between 0.05 μm and 2 μm, in particular for instance between 0.1 m and 1 μm, for example 0.5 μm.

The resistance R of the lines 11, 12, 13, 14, 15 can be calculated with the help of the following formula (already mentioned above):
R=(L/W)Rₛₕ

This results—for example at a specific resistance Rₛₕ of for instance 0.04Ω/sq, and of a width W of for instance 0.51 μm—in a resistance R_{L} per length L of 80Ω/mm.

The above lines 11, 12, 13, 14, 15 can be relatively long, and can in particular for instance extend over a substantial part of the semi-conductor component surface. For example the lines 11, 12, 13, 14, 15 can for instance be longer than for instance 0.1 mm, 1 mm or 3 mm, for instance between 0.1 mm and 40 mm, in particular between 0.5 mm and 20 mm, advantageously between 1 mm and 15 mm, etc., for instance ca. 6 mm.

As is apparent from FIG. 1, the above lines 11, 12, 13, 14, 15 (or alternatively:

sections of the lines in each case corresponding with the lines shown in Figure) run essentially parallel to one another and are all essentially of the same length L.

Each of the above lines 11, 12, 13, 14, 15 is sub-divided into two—essentially equally long—line sections 11a, 11b, 12a, 12b, 13a, 13b, 14a, 14b, 15a, 15b (whereby each of the sections then has a length of ca. L/2, for instance of between 0.5 mm and 7.5 mm, for example 3 mm).

As is apparent from FIG. 1, an appropriate line amplifier device 101, 102, 103, 104, 105 and/or buffer is in each case connected between a first line section 11a, 12a, 13a, 14a, 15a of the above lines 11, 12, 13, 14, 15, and a corresponding second line section 11b, 12b, 13b, 14b, 15b of the above lines 11, 12, 13, 14, 15.

The signals S1, S2′, S3, S4′, S5 provided by corresponding signal driver devices (“drivers”) 7a, 7b, 7c, 7d, 7e—for instance provided in the semi-conductor components 3—and applied to the above first line sections 11a, 12a, 13a, 14a, 15a of the above lines 11, 12, 13, 14, 15, are relayed via the corresponding first line sections 11a, 12a, 13a, 14a, 15a of the above lines 11, 12, 13, 14, 15 to the respective line amplifier device 101, 102, 103, 104, 105 and/or buffer, where they are (briefly) buffered and/or amplified.

The corresponding (briefly) buffered and/or amplified signals (here: the signals S1, S2″, S3, S4″, S5) are relayed from the line amplifier devices 101, 102, 103, 104, 105 and/or buffers via the corresponding second line sections 11b, 12b, 13b, 14b, 15b of the above lines 11, 12, 13, 14, 15 to corresponding signal receptor devices (“receivers”) 8a, 8b, 8c, 8d, 8 provided for instance in the semi-conductor component 4.

The above line amplifier devices 101, 102, 103, 104, 105 and/or buffers can for instance in each case lead to a signal delay time increased by a line amplifier and/or buffer signal delay time τ_{buffer} f, whereby τ_{buffer} can for instance amount to between 10 ps and 500 ps, in particular for instance to between 50 ps and 400 ps, for example 200 ps.

The above line amplifier devices 101, 102, 103, 104, 105 and/or buffers can be advantageously constructed and/or arranged in such a way, that the result for all of them, despite their possibly different construction methods (see below), is an essentially identical signal delay time (i.e. that τ_{buffer} is essentially identical for all line amplifier devices 101, 102, 103, 104, 105 and/or buffers (i.e. that it falls within narrow bounds, for instance <±20 ps, in particular <±10 ps)).

As schematically illustrated in FIG. 1, each line amplifier device 101, 102, 103, 104, 105 and/or buffer can in each case contain one or more series-connected inverters 101a, 101b, 102a, 102b, 102c, 103a, 103b, 104a, 104b, 104c, 105a, 105b, in particular—as is more closely described below—either an even or an odd number of inverters 101a, 11b, 102a, 102b, 102c, 103a, 103b, 104a, 104b, 104c, 105a, 105b.

In particular—as is also apparent from FIG. 1-a line amplifier device 101, 102, 103, 104, 105 and/or buffer in each case containing an even number (here for instance two) and an uneven number (here for instance three) of inverters—is in each case alternately connected with adjoining lines 11, 12, 13, 14, 15 (i.e. alternately with a non-inverting and an inverting line amplifier device 101, 102, 103, 104, 105).

This has the effect that in a first line amplifier device 101 and/or buffer—connected with the first line 11—a signal S1 emitted to the corresponding second line section 11b corresponds with the signal S1 input via the corresponding first line section 11a into the line amplifier device 101 (i.e. it is amplified and/or delayed in comparison to it, but not however inverted).

In contrast to this, at a second line amplifier device 102 and/or buffer—connected with the second line 12 which adjoins the first line 11—a signal S2″ is emitted at the corresponding second line section 12b, which signal S″ is inverted in relation to signal S2′ input via the corresponding first line section 12a into the second line amplifier device 102 and/or buffer (and additionally amplified and/or delayed in comparison with it).

In converse fashion (and correspondingly similar to the first line 11) a signal S3 is emitted by a third amplifier device 103 and/or buffer—connected with the third line 13 which adjoins the second line 12—to the corresponding second line section 13b, which signal S3 corresponds with the signal S3 input via the corresponding first line section 13a (i.e. amplified and/or delayed in comparison with it, but not however inverted).

Again in contrast to this (and correspondingly similar to the second line 12) a signal S4″ is emitted by a fourth line amplifier device 104 and/or buffer—connected with the fourth line 14 which adjoins the third line 13—to a corresponding second line section 14b, which signal is inverted in relation to signal S4′ input into the fourth line amplifier device 104 and/or buffer via the corresponding first line section 14a (and additionally amplified and/or delayed in comparison with it).

Again in contrast to this (and correspondingly similar to the first and third lines 11, 13) a signal S5 is emitted by a fifth line amplifier device 105 and/or buffer—connected with the fifth line 15 which adjoins line 14—to a corresponding second line section 15b, which signal corresponds with the signal S5 input via the corresponding first line section 15a (i.e. amplified and/or delayed, not however inverted in comparison with it), etc., etc.

In other words, in the case of a particular line 11, 13, 15, to which a non-inverting line amplifier device 101, 103, 105 and/or buffer has been connected, an inverting line amplifier device 102, 104 and/or buffer is then in each case connected vice versa with lines 12, 14, which (immediately) adjoin lines 11, 13, 15.

Correspondingly inverted, in the case of a particular line 12, 14, to which an inverting line amplifier device 102, 104 and/or buffer has been connected, a corresponding non-inverting line amplifier device 101, 103, 105 and/or buffer is then in each case vice versa connected with lines 11 12, 13, which (immediately) adjoin lines 12, 14.

To prevent corresponding inverse signals from arriving at the appropriate signal receptor devices (“receivers”) 8b, 8d,—connected with lines 12, 14 by means of inverting line amplifier devices 102, 104 and/or buffers—and not perhaps the signals S2, S4 actually needing to be relayed, (i.e. for example vice versa, to ensure that signals S2″, S4″, which are not inverted in relation to the signals S2, S4, which actually need to be relayed (although retarded in relation to them) arrive there) the corresponding signal driver devices 7b, 7d—connected with lines 12, 14 by means of inverting line amplifier devices 102, 104 and/or buffers—have in each case been constructed as inverting signal driver devices 7b, 7d.

In contrast to this, the corresponding signal driver devices 7a, 7c, 7e—connected with lines 11, 13, 15 by means of non-inverting line amplifier devices 101, 103, 105 and/or buffers—been constructed as non-inverting signal driver devices 7a, 7c, 7e.

For example—as is apparent from FIG. 1—a signal driver device 7a, 7b, 7c, 7d, 7e, in each case containing an alternately even (here: for instance two) and an odd (here: for instance three) number of inverters, can in each case be connected with adjoining lines 11, 12, 13, 14, 15.

It this way it can be achieved that the signals (here: the signals S1, S2, S3, S4, S5) input into each of the signal driver devices 7a, 7b, 7c, 7d, 7e—irrespective of whether the line allocated in each case is connected with a non-inverting line amplifier device 101, 103, 105 and/or buffer, or with an inverting line amplifier device 102, 104 and/or buffer—are present at corresponding inputs of the above signal receptor devices (“receivers”) 8a, 8b, 8c, 8d, 8e, as signals corresponding with the signals S1, S2, S3, S4, S5 entered in each case (here: present as signals S1, S2″, S3, S4″, S5), delayed however in relation to them, and that the signals are—for instance in a correspondingly non-inverted fashion—amplified by the receivers.

As is further apparent from FIG. 1, the signal receptor devices (“receivers”) 8a, 8b, 8c, 8d, 8e can for instance in each case include a number of inverters, for instance in each case an even number of inverters (for instance two or more corresponding inverters).

By means of alternately and/or successively providing non-inverting (conventional) inverting line amplifier devices 101, 102, 103, 104, 105 as above, the following technical effect can be achieved:

As already described in the introduction to the present patent registration, the actual effective capacitance C of a line (for instance of line 12 shown in FIG. 1) depends relatively strongly on the signal (for instance the signal S2′, S2″) present on the respective line, (which signal—in particular in digital systems, and for instance also in the present embodiment example (expressed in simplified fashion)—can, at a particular instant for instance remain the same (“o”), rise (“+”), or fall (“−”)) and on signals (for instance the signals S1, S3) present on the respective immediately neighboring lines (for instance the lines 11, 13 shown in FIG. 1) of the same metallization and/or wiring level (for instance the wiring level 5a) (whereby the signal present on a first neighboring line (for instance one lying to the left of the line) can at a particular instant for instance remain constant (“o”), increase (“+”), or decrease (“−”), and whereby—correspondingly—the signal present on a second neighboring line (for instance lying to the right of the line) can, at a particular instant—also—for instance remain the same (“o”), increase (“+”), or decrease (“−”)).

In the present embodiment example, the data patterns present on a corresponding first line section (for instance on the line section 12a), on a line (for instance the line 12), and on corresponding first line sections (for instance the line sections 11a, 13a), on corresponding neighboring lines (for instance the lines 11, 13) (for instance—in relation to the third adjoining lines 11, 12, 13 (depending on whether the respective signals remain the same, increase, or decrease)—either “+++”: or “++o”, or “++−”, or “+o+”, or “+oo”, or “+o−”, or “+−+”, or “+−o”, or “+−”, or “o++”, or “o+o”, or “o+−”, etc.), are correspondingly alternately and/or successively modified in a pre-determined way by means of the above non-inverting and inverting line amplifier devices (for instance the non-inverting line amplifier devices 101, 103, and the inverting line amplifier device 102) for the corresponding second line sections (for instance the second line section 12b of the line 12, and the corresponding second line sections 11b, 13b of the corresponding neighboring lines 11, 13) (in such a way for instance that the above data patterns are changed into appropriate data patterns “+−+”, or “+−o”, or “+−”, or “+o+”, or “+oo”, or “+o−”, or “+++”, or “++o”, or “++−” or “o−+”, or “o−o”, or “o−−”, etc present on corresponding second line sections)).

In this way it can be achieved that a total signal delay time of τ_{ges}=τ_{buffer}+τ1+τ2 results for the lines 11, 12, 13, 14, 15, which delay time is independent or essentially independent of the data patterns present on lines 11, 12, 13, 14, 15, (whereby τ1 is the signal delay time generated by the respective first line sections 11a, 12a, 13a, 14a, 15a, and τ2 is the signal delay time—which may differ from t1 despite the same line section length L/2—generated by the respective second line sections 11b, 12b, 13b, 14b, 15b):

The following, differing values for the actual effective capacitance per length C_{L} can result in regard to a particular line section—depending on the signals present on the line and on the respective neighboring lines—(here represented in relation to the example of an increasing and a decreasing signal on the line in question):

| Signal state | | Signal state | |
|---|---|---|---|
| on the line | | on the line | |
| section of the | | section of the | |
| neighboring line | Signal state | neighboring line | |
| lying to the | on the | lying to the | Effective actual |
| left of the | respective | right of the | capacitance per |
| respective line | line section | respective line | length C_{L} |
| + | + | + | CH_{L} |
| + | + | O | CH_{L} + 1CV_{L} |
| + | + | − | CH_{L} + 2CV_{L} |
| O | + | O | CH_{L} + 2CV_{L} |
| − | + | O | CH_{L} + 3CV_{L} |
| − | + | − | CH_{L} + 4CV_{L} |
| + | − | + | CH_{L} + 4CV_{L} |
| + | − | O | CH_{L} + 3CV_{L} |
| + | − | − | CH_{L} + 2CV_{L} |
| O | − | O | CH_{L} + 2CV_{L} |
| − | − | O | CH_{L} + 1CV_{L} |
| − | − | − | CH_{L} |

For the above line 12 (which is surrounded by the above lines 11, 13) the following total signal delay time τ_{ges} for instance is achieved with a length of for instance 3 mm for the first and second line sections 11a, 11b, 12a, 12b, 13a, 13b, 14a, 14b, 15a, 15b, (using the abbreviations R₃=R_{L}*3 mm, CH₃=CH_{L}*3 mm, and CV₃=CV_{L}*3 mm):

| Data patterns | Data patterns | |
|---|---|---|
| present on the first | present on the | |
| line sections | second line | |
| arranged before the | sections arranged | |
| buffers | behind the buffers | Total signal delay time τ_{ges} |
| +++ | +−+ | τ_{buffer} + 0.7R₃[(CH₃ + 0CV₃) + |
| | | (CH₃ + 4CV₃)] |
| ++o | +−o | τ_{buffer} + 0.7R₃[(CH₃ + 1CV₃) + |
| | | (CH₃ + 3CV₃)] |
| ++− | +−− | τ_{buffer} + 0.7R₃[(CH₃ + 2CV₃) + |
| | | (CH₃ + 2CV₃)] |
| o+o | o−o | τ_{buffer} + 0.7R₃[(CH₃ + 2CV₃) + |
| | | (CH₃ + 2CV₃)] |
| −+o | −−o | τ_{buffer} + 0.7R₃[(CH₃ + 3CV₃) + |
| | | (CH₃ + 1CV₃)] |
| −+− | −−− | τ_{buffer} + 0.7R₃[(CH₃ + 4CV₃) + |
| | | (CH₃ + 0CV₃)] |

For the total signal delay time τ_{ges}, in all cases (irrespective of the data patterns applied by the respective signal driver devices 7a, 7b, 7c to corresponding lines 11, 12, 13 (in particular to the line sections 11a, 12a, 13a)) the following result is found:
τ_{ges}=τ_{buffer}+0.7R₃(2CH₃+4CV₃)
and consequently (for the numerical values quoted above)
τ_{ges}=500 ps

In this way—even without the use of screening lines—the result can be achieved that the respective total signal delay times ages for the lines 11, 12, 13, 14, 15 is non-reliant on and/or essentially independent of the data patterns present on lines 11, 12, 13, 14, 15.

What is claimed is:

1. A bus system with a line, and two adjoining lines, whereby the lines each comprise two line sections, which are connected with one another by means of at least one of a line amplifier and buffer device, at least one of the line amplifier and buffer device connected with the line sections of the line is constructed as at least one of an inverting line amplifier and buffer device, and at least one of the amplifier and buffer devices connected with the line sections of the adjoining lines are constructed as at least one of a non-inverting line amplifier and buffer devices.

2. A bus system with a line, and two adjoining lines, whereby the lines each comprise two line sections, which are connected with one another by means of at least one of a line amplifier and buffer device, at least one of the line amplifier and buffer device connected with the line sections of the line is constructed as at least one of a non-inverting line amplifier and buffer device, and at least one of the line amplifier and buffer devices connected with the line sections of the adjoining lines are constructed as at least one of an inverting line amplifier and buffer devices.

3. The bus system according to claim 1, wherein the line sections are essentially of an equal length.

4. The bus system according to claim 1, wherein the lines are connected with signal driver devices, which apply appropriate signals to the lines, whereby the signal driver device connected with the line is constructed as an inverting signal driver device, and the signal driver devices connected with the adjoining lines are constructed as non-inverting signal driver devices.

5. The bus system according to claim 1, wherein the lines are connected with signal driver devices, which apply appropriate signals to the lines, whereby the signal driver device connected with the line is constructed as a non-inverting signal driver device, and the signal driver devices connected with the adjoining lines are constructed as inverting signal driver devices.

6. The bus system according to claim 1, wherein the lines are connected with signal receptor devices, which receive signals present on the lines, whereby the signal receptor device connected with the line is constructed as an inverting signal receptor device, and the signal receptor devices connected with the adjoining lines are constructed as non-inverting signal receptor devices.

7. The bus system according to claim 1, wherein the lines are connected with signal receptor devices, which receive signals present on the lines, whereby the signal receptor device connected with the line is constructed as a non-inverting signal receptor device, and the signal receptor devices connected with the adjoining lines are constructed as inverting signal receptor devices.

8. The bus system according to claim 1, wherein no lines are used as screening lines are provided between the line, and the adjoining lines.

9. The bus system according to claim 1, wherein the lines in each case comprise one or more essentially equally long line sections, in each case connected with one another by means of one or more further line amplifier and/or buffer devices.

10. The bus system according to claim 1, with one or more additional lines, whereby the additional lines each comprise two line sections which are connected with one another by means of at least one of a line amplifier and buffer device, wherein at least one of the line amplifier and buffer devices connected with the line sections of the lines, in each case in relation to adjoining lines, are alternatingly constructed as at least one of inverting and non-inverting line amplifier and buffer devices.

11. A procedure for operating a bus system, with a line, and two adjoining lines, whereby the lines each comprise two line sections, which are connected with one another by means of at least one of a line amplifier and buffer device, comprising:
inverting amplification and/or buffering of the signals present on the line by means of the line amplifier and/or buffer device connected with the line sections of the line; and
non-inverting amplification and/or buffering of the signals present on the adjoining lines by means of the line amplifier and/or buffer devices connected with the line sections of the adjoining lines.

12. A procedure for operating a bus system, with a line, and two adjoining lines, whereby the lines each comprise two line sections, which are connected with one another by means of at least one of a line amplifier and buffer device, comprising:
non-inverting amplification and/or buffering of the signals present on the line by means of the line amplifier and/or buffer device connected with the line sections of the line; and
inverting amplification and/or buffering of the signals present on the adjoining lines by means of the line amplifier and/or buffer devices connected with the line sections of the adjoining lines.
